(19) United States
(12) Patent Application Publication
(10) Pub. No.: US 2026/0365048 A1
(43) Pub. Date: Nov. 19, 2026

(54) APPARATUS AND METHOD FOR DETERMINING POWER AVAILABILITY TIME OF FUEL CELL VEHICLE

(71) Applicants: Hyundai Motor Company, Seoul (KR); Kia Corporation, Seoul (KR)

(72) Inventors: Hyung Seok Choi, Hwaseong-si (KR); Jae Ok Ha, Hwaseong-si (KR); Dae Jong Kim, Hwaseong-si (KR); Jae Ho Han, Hwaseong-si (KR)

(73) Assignees: Hyundai Motor Company, Seoul (KR); Kia Corporation, Seoul (KR)

(21) Appl. No.: 19/400,799

(22) Filed: Nov. 25, 2025

(30) Foreign Application Priority Data
May 14, 2025 (KR) 10-2025-0062669

(51) Int. Cl. B60L 50/75; B60L 55/00; G01R 31/382; H01M 8/04537

(52) U.S. Cl. CPC B60L 50/75; B60L 55/00; G01R 31/382; H01M 8/04619; B60L 2250/16

(57) ABSTRACT

Provided is an apparatus for determining a power availability time of a fuel cell vehicle including a battery installed in the vehicle, a fuel cell stack configured to generate power allowed to be supplied to the battery, and a processor configured to determine a currently available total power amount based on a state of charge (SoC) of the battery and a state of fuel (SoF) of the fuel cell stack based on power stored in the battery and power generated by the fuel cell stack being supplied to a load of the vehicle, and to determine a remaining time during which power is allowed to be supplied to an internal load and an external load of the vehicle based on a power consumption amount of the internal load and the external load and the total power amount.

### CROSS-REFERENCE TO RELATED APPLICATION

This application claims, under 35 U.S.C. § 119(a), the benefit of and priority to Korean Patent Application No. 10-2025-0062669 filed on May 14, 2025, the entire contents of which are incorporated herein by reference in their entirety.

### BACKGROUND

### (a) Technical Field

The present disclosure relates to an apparatus and method for determining a power availability time of a fuel cell vehicle. More particularly, it relates to an apparatus and method for determining a power availability time of a fuel cell vehicle for determining a time for which electrical energy of a battery installed in a vehicle is utilizable outside the vehicle.

### (b) Background Art

Recent developments in the automotive sector, especially in eco-friendly vehicles like hybrids and fully electric models, manufacturers have increasingly integrated a Vehicle-to-Load (V2L) functionality. This feature enables users to harness power from the vehicle's battery for external applications, thereby enhancing the utility and convenience of the vehicle beyond mere transportation. The V2L capability also allows users to connect various devices and appliances directly to the vehicle. For example, the V2L helps to facilitate activities such as camping, emergency power supply during outages, or even routine household tasks, underscoring the vehicle's role as a mobile energy source.

V2L converts the vehicle's stored battery energy into household-grade AC power, enabling direct use with electronic devices. By doing so, this effective extends the utility of electric vehicles (EVs) beyond conventional transportation. By enabling the supply of this AC power to external devices, the V2L function stands as a significant innovation in the realm of energy flexibility and consumer convenience.

While V2L is commonly associated with battery electric vehicles, its integration into fuel cell vehicles introduces unique operational considerations. In a fuel cell vehicle, a fuel cell stack is integrated into the power supply system, enabling the charging of the vehicle's battery. The system operates in three modes: the power-on mode, where energy is solely drawn from the battery; the utility mode, which activates the fuel cell stack to generate power; and the drive-ready mode, positioning the vehicle for operation. The V2L functionality is available during the power-on mode, but its duration is contingent upon the state of charge (SoC) of the battery. As the SoC diminishes and approaches a critical threshold, the power supply system transitions to either the utility mode or the drive-ready mode to preserve battery integrity.

In utility mode, the system simultaneously engages both the battery and the fuel cell stack, effectively balancing energy sources when the vehicle is stationary. Conversely, in drive-ready mode, these energy sources work together to prepare the vehicle for operation. In cases where the fuel cell stack is engaged, it contributes by supplying electrical energy to recharge the battery. This careful orchestration of operational modes ensures that the vehicle can effectively manage energy consumption and charging requirements while maintaining optimal performance and usability. As such, the integration of these functionalities within the fuel cell vehicle's power supply system underscores the importance of efficient energy management in modern automotive engineering.

The conventional fuel cell vehicle enhances user experience by displaying the remaining time for the V2L functionality, ensuring users can plan their energy usage effectively. The calculation of this remaining time relies on accurate data regarding both the SoC of the battery, as provided by the Battery Management System (BMS), and the state of fuel (SoF) of the fuel cell stack, as reported by the Fuel Cell Control Unit (FCU). To facilitate this process, a central processor gathers SoC and SoF information via wired communication channels connecting the BMS and FCU.

However, challenges can arise during information retrieval that may compromise the accuracy of the remaining time estimation. These challenges include potential communication mismatches in timing cycles between the processor, BMS, and FCU, which can lead to missed data transmissions. Additionally, discrepancies in data resolution between the SoF and SoC can result in suboptimal data quality, further complicating accurate calculations. Such errors significantly impact the precision of the remaining time determination, ultimately providing users with misleading information about the V2L functionality's available duration. Addressing these communication and resolution issues is critical for improving user confidence in the feedback provided by fuel cell vehicles. Thus, there is a need for improved methods to determine the power availability time of a fuel cell vehicle capable.

### SUMMARY OF THE DISCLOSURE

An aspect of the disclosed embodiments is to provide an apparatus and method for determining a power availability time of a fuel cell vehicle capable of accurately determining a remaining time during which a V2L function is available.

An aspect of the disclosed embodiments is not limited to the aspect mentioned above, and other aspects of the present disclosure not mentioned above will be clearly understood by those skilled in the art to which the present disclosure pertains from the description below.

In aspects, the present disclosure provides an apparatus for determining a power availability time of a fuel cell vehicle, the apparatus including a battery installed in the vehicle, a fuel cell stack configured to generate power allowed to be supplied to the battery, and a processor configured to determine a currently available total power amount based on a state of charge (SoC) of the battery and a state of fuel (SoF) of the fuel cell stack based on power stored in the battery and power generated by the fuel cell stack being supplied to a load of the vehicle, and to determine a remaining time during which power is allowed to be supplied to an internal load and an external load of the vehicle based on a power consumption amount of the internal load and the external load and the total power amount.

In embodiments, the processor may determine the remaining time based on the battery not being charged.

In embodiments, the processor may determine a real-time SoF determined based on the external load being connected to the battery as a first SoF, determine an accumulated amount of power consumption used by the external load and the internal load based on a difference between the first SoF and a current SoF being less than a predetermined value, and determine a real-time remaining power amount by subtracting the accumulated power consumption amount from the total power amount.

In embodiments, the processor may determine a real-time SoF determined based on the external load being connected to the battery as a first SoF, and redetermine the total power amount based on the SoC of the battery and the SoF of the fuel cell stack based on a difference between the first SoF and a current SoF being greater than or equal to a predetermined value.

In embodiments, the processor may redetermine the first SoF based on the total power amount being redetermined, and the first SoF may be determined to be a real-time SoF redetermined based on the total power amount being redetermined.

In embodiments, based on a time for which the external load has been connected to the battery being less than a predetermined first time, the processor may determine the remaining time at intervals of a predetermined second time.

In embodiments, based on the time for which the external load has been connected to the battery being greater than or equal to the first time, the processor may determine the remaining time at intervals of a predetermined third time.

In embodiments, the processor may display the remaining time through a display of the vehicle.

In embodiments, the processor may determine the remaining time based on the accumulated power consumption amount, an average power consumption amount which is an average value of the accumulated power consumption amount, and the total power amount.

In embodiments, the processor may receive information on the SoC of the battery from a BMS (Battery Management System) of the vehicle, and receive information on the SoF of the fuel cell stack from a FCU (Fuel cell Control Unit) of the vehicle.

In aspects, the present disclosure provides a method of determining a power availability time of a fuel cell vehicle, the method including determining, by a processor, whether power of a battery installed in the vehicle and power of a fuel cell stack are supplied to a load of the vehicle, determining, by the processor, an SoC of the battery based on power of the battery and the fuel cell stack being supplied to a load, determining, by the processor, an SoF of the fuel cell stack based on the power of the battery and the fuel cell stack being supplied to the load, determining, by the processor, a currently available total power amount based on the SoC of the battery and the SoF of the fuel cell stack, and determining, by the processor, a remaining time during which power is allowed to be supplied to an internal load and an external load of the vehicle based on a power consumption amount of the internal load and the external load and the total power amount.

It is understood that the term “vehicle” or “vehicular” or other similar terms as used herein is inclusive of motor vehicles in general such as passenger automobiles including sport utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example, vehicles powered by both gasoline and electricity.

The above and other features of the disclosure are discussed infra.

### BRIEF DESCRIPTION OF THE DRAWINGS

The above and other features of the present disclosure will now be described in detail with reference to certain exemplary embodiments thereof illustrated in the accompanying drawings which are given hereinbelow by way of illustration only, and thus are not limitative of the present disclosure, and wherein:

FIG. 1 is a configuration diagram illustrating an apparatus for determining a power availability time of a fuel cell vehicle according to an embodiment of the present disclosure; and

FIG. 2 is a flowchart illustrating a process of determining a power availability time of a fuel cell vehicle according to an embodiment of the present disclosure.

It should be understood that the appended drawings are not necessarily to scale, presenting a somewhat simplified representation of various features illustrative of the basic principles of the disclosure. The specific design features of the present disclosure as disclosed herein, including, for example, specific dimensions, orientations, locations, and shapes will be determined in part by the particular intended application and use environment.

In the figures, reference numbers refer to the same or equivalent parts of the present disclosure throughout the several figures of the drawing.

### DETAILED DESCRIPTION

Hereinafter, embodiments of the present disclosure will be described with reference to the attached drawings. Matters included in the attached drawings are schematically illustrated for ease of description of embodiments of the present disclosure and may differ from an actually implemented form. In addition, in description with reference to the attached drawings, identical or corresponding components may be assigned the same drawing numbers, and redundant descriptions thereof may be omitted.

In addition, the terms “ . . . section”, “ . . . unit”, “ . . . module”, etc., described in the specification mean a unit that processes at least one function or operation, which may be implemented by hardware, software, or a combination of hardware and software.

In addition, the terms used in the specification are only used to describe particular embodiments and are not intended to limit the embodiments. A singular expression includes a plural expression unless the context clearly dictates otherwise.

In addition, even though the terms “first” and “second” in this Specification may be used to describe various components, the components are not limited by the terms. The terms are only used to distinguish one component from other components. Accordingly, without departing from the scope of rights according to the concept of the present disclosure, a first component may be referred to as a second component, and the second component may be referred to as the first component.

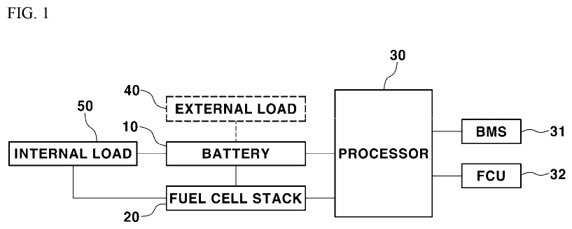

As illustrated in FIG. 1, an apparatus for determining a power availability time of a fuel cell vehicle according to an embodiment of the present disclosure includes a battery 10, a fuel cell stack 20, and a processor 30.

The battery 10 and the fuel cell stack 20 are installed in the fuel cell vehicle. Although not shown in the drawing, each of the battery 10 and the fuel cell stack 20 may be connected to an electric motor used as a power source of the fuel cell vehicle so that power may be supplied.

The fuel cell vehicle (referred to hereinafter as “vehicle”) may include hardware for electrical connection between the battery 10 and an external load 40 of the vehicle. For example, the vehicle may be equipped with an external discharge port for connection to the external load 40, and the external discharge port may be equipped with an electrical connection terminal that may be connected to the external load 40. In addition, the external discharge port may be connected to the battery 10 installed inside the vehicle through a V2L converter.

The battery 10 and the fuel cell stack 20 are electrically connected to an internal load 50 of the vehicle, and may optionally supply power to the internal load 50. For example, the internal load 50 may include a radiator, an air conditioner, a heater for the fuel cell stack, etc. provided inside the vehicle, and may include the V2L converter and the electric motor for interconnecting the battery 10 and the internal load 50.

In addition, the battery 10 is optionally connected to the external load 40 of the vehicle. By electrically connecting the battery 10 to the external load 40, a V2L function for using, outside the vehicle, power stored in the battery 10 and power generated by the fuel cell stack 20 may be executed. The power generated by the fuel cell stack 20 may be supplied to the external load 40 through the battery 10. The external load 40 is separately provided outside the vehicle, and may include, for example, a household electronic device.

The fuel cell stack 20 may be electrically connected to the battery 10 inside the vehicle. The fuel cell stack 20 may be configured to generate electrical energy through an electrochemical reaction using a fuel and an oxidizer. Hydrogen may be used as the fuel, and air may be used as the oxidizer.

When the fuel cell stack 20 is driven, the battery 10 may be selectively charged. According to an embodiment of the present disclosure, when the fuel cell stack 20 is driven, power output from the fuel cell stack 20 may be supplied to the battery 10 to charge the battery 10, or supplied to the internal load 50 such as the electric motor and consumed. For example, depending on the SoC value of the battery 10, the battery 10 may or may not be charged with the power of the fuel cell stack 20. The vehicle may be equipped with hardware for converting the electrical energy output from the fuel cell stack 20 into a form with which the battery 10 may be charged.

The processor 30 may receive information on the SoC of the battery 10 from a BMS 31 equipped in the vehicle. In addition, the processor 30 may receive information on the SoF of the fuel cell stack 20 from an FCU 32 of the vehicle. The processor 30 is communicably connected to the BMS 31 and the FCU 32. The processor 30 may be connected to the BMS 31 and the FCU 32 through wired or wireless communication of the vehicle. For example, the processor 30 may exchange information with the BMS 31 and the FCU 32 through CAN communication of the vehicle. The BMS 31 controls and manages discharging and charging of the battery 10, and may determine the SoC of the battery 10 in real time. The FCU 32 controls and manages operation of the fuel cell stack 20, and may calculate the SoF of the fuel cell stack 20 in real time.

The BMS 31 may determine the real-time SoC of the battery 10 based on an output voltage, an output current, a real-time temperature of the battery 10, a load connected to the battery 10, etc. According to an embodiment of the present disclosure, although not shown in the drawing, the output voltage and the output current of the battery 10 may be measured through a detection means such as a sensor installed at an output terminal of the battery 10, and the real-time temperature of the battery 10 may be measured through a temperature sensor attached to the battery 10. Since a method of determining the SoC of the battery 10 is well known, a detailed description thereof will be omitted.

The FCU 32 may determine the real-time SoF of the fuel cell stack 20 based on the fuel pressure in a fuel tank where a fuel for the fuel cell stack 20 is stored, a fuel temperature in the fuel tank, and the fuel mass in the fuel tank. The real-time SoF of the fuel cell stack 20 indicates the remaining fuel amount in the fuel tank. Although not shown in the drawing, the fuel pressure and the fuel temperature in the fuel tank may be estimated based on a measurement value of the pressure sensor and a measurement value of the temperature sensor installed at an outlet of the fuel cell stack 20. Since a method of determining the SoF of the fuel cell stack 20 is well known, a detailed description thereof will be omitted.

The processor 30 may determine a remaining time T during which the power of the battery 10 and the fuel cell stack 20 may be supplied to the internal load 50 and the external load 40 of the vehicle by using SoC information received from the BMS 31 and SoF information received from the FCU 32.

The processor 30 may determine that determination of the remaining time T is necessary when the external load 40 is connected to the battery 10 of the vehicle, the external load 40 is consuming the power of the battery 10, and the fuel cell stack 20 is operating. In other words, the processor 30 may determine that determination of the remaining time T is necessary when the power stored in the battery 10 and the power generated in the fuel cell stack 20 are being supplied to the load of the vehicle. The load of the vehicle includes the internal load 50 and the external load 40.

The fuel cell stack 20 may be driven when a power supply system of the vehicle is in a utility mode or a drive-ready mode. The utility mode is a mode in which both the battery 10 and the fuel cell stack 20 are used when the vehicle is not driving, and the drive-ready mode is a mode in which both the battery 10 and the fuel cell stack 20 are used when the vehicle is in a drivable state.

The processor 30 may determine the remaining time T by converting an SoC value received from the BMS 31 and an SoF value received from the FCU 32 into power values kWh. According to an embodiment of the present disclosure, the processor 30 may determine the total power amount P of the battery 10 currently available based on the real-time SoC of the battery 10 and the real-time SoF of the fuel cell stack 20. The total power amount P may refer to the total power amount that may be supplied to the current internal load 50 and the external load 40.

Specifically, the processor 30 may determine the total power amount P as in the following Equation 1.
Equation 1: Total power amount (P)=6.69×(real-time SoF−V2L usage lower limit SoF)/100×33.3 (kWh/kg)×system efficiency/100+(real-time SoC−first SoC)/100×total energy amount of battery×0.001 (kWh/kg)

Here, 6.69, 33.3, and 0.001 are predetermined proportional constants. The real-time SoF is the remaining fuel amount of the fuel tank that stores the fuel supplied to the fuel cell stack 20. That is, the real-time SoF may refer to the remaining amount of fuel that may be supplied to the fuel cell stack 20. The V2L usage lower limit SoF is a lower limit SoF allowing the V2L function to be used. The system efficiency is efficiency of a fuel cell system installed in the vehicle. The real-time SoC is a real-time SoC of the battery 10. The first SoC is an SoC of the battery 10 determined based on a time point when driving suspension of the fuel cell stack 20 is released. The total energy amount of the battery is the total energy amount at the beginning of production, which is determined in advance according to the specifications of the battery 10, and may be, for example, 2640 Wh. As the V2L usage lower limit SoF, the system efficiency, and the first SoC, values determined in advance are used, and values tuned through experiments may be used.

In addition, the processor 30 may determine a real-time power consumption amount P1 and an average power consumption amount P2 in order to determine the remaining time T. The real-time power consumption amount P1 is a power amount obtained by adding the power amount consumed in real time by the internal load 50 and the power amount consumed in real time by the external load 40. For example, the real-time power consumption amount P1 may be determined based on measurement values of a voltage sensor and a current sensor installed at output terminals of the battery 10 and the fuel cell stack 20, respectively.

The average power consumption amount P2 is a value obtained by dividing an accumulated power consumption amount P3 by a V2L usage time. The accumulated power consumption amount P3 is a value obtained by accumulating and summing the real-time power consumption amount P1 during the V2L usage time. In other words, the accumulated power consumption amount P3 is the power consumption amount used by the external load 40 and the internal load 50 during the V2L usage time. The V2L usage time is a time elapsed from a time point when the external load 40 is connected to the battery 10. In other words, the V2L usage time is a time during which the external load 40 is connected to the battery 10 and uses the power of the battery 10. In other words, the average power consumption amount P2 is an average value of the power consumed in real time by the internal load 50 and the external load 40 connected to the battery 10.

The processor 30 may determine a currently available real-time remaining power amount P4 by subtracting the accumulated power consumption amount P3 from the total power amount P. The real-time remaining power amount P4 may be determined as a value less than or equal to the total power amount P. The real-time remaining power amount P4 is remaining power that may be supplied to the internal load 50 and the external load 40.

The processor 30 may determine the remaining time T by dividing the real-time remaining power amount P4 by the average power consumption amount P2. The remaining time T may be determined as shown in the following Equation 2.
Equation 2: Remaining time (T)=Real-time remaining power amount P4/average power consumption amount P2

Meanwhile, remaining power amount of a power supply in the vehicle may be determined using two methods. The first is a method of determining the total power amount P by converting the SoF and the SoC into power amount (Wh) when the external load 40 is connected to the battery 10 according to the present disclosure, and then deducting the accumulated power consumption amount P3 from the total power amount P. The second is a method of directly converting the real-time SoF and the real-time SoC into the currently available power amount according to the conventional technology.

In the case of a fuel cell vehicle that uses hydrogen as a fuel, information on both the SoF and the SoC is required to determine the currently available remaining power. However, during a process in which the processor 30 receives information from the BMS 31 and the FCU 32, information reception may be missed due to mismatch in the communication cycle between the processor, the BMS, and the FCU, or accuracy of the information received by the processor may decrease due to a difference between the resolution of the SoF and the resolution of the SoC. In addition, since the SoF of the fuel cell vehicle is determined based on the pressure and temperature inside the fuel tank, there is a limit to accurate determination. In this situation, when the currently available remaining power is determined using only the information on the real-time SoF and the real-time SoC, determination errors increase.

In the case of the present disclosure, the real-time remaining power amount P4 is determined using the total power amount P and the accumulated power consumption amount P3. In addition, the total power amount P is redetermined whenever the SoF of the fuel cell stack 20 decreases by more than a predetermined SoF value α. Accordingly, an error that may occur may be reduced compared to the case where the real-time SoF and the real-time SoC are directly converted into power amount values. The value α is a value that may be tuned through a preliminary test and evaluation. According to an embodiment of the present disclosure, the SoF value α may decrease as the SoF of the fuel cell stack 20 increases.

In addition, when determining the remaining time T by dividing the real-time remaining power amount P4 by the real-time power consumption amount P1, the variation of the remaining time T increases. Accordingly, the present disclosure may improve accuracy of determining the remaining time T by dividing the real-time remaining power amount P4 by the average power consumption amount P2.

As the V2L usage time increases, the variation of the remaining time T decreases, but in an initial stage when the external load 40 is connected to the battery 10 (i.e., in the initial stage of V2L usage), reliability and accuracy may be insufficient due to insufficient data for determining the average power consumption amount P2. Therefore, in the present disclosure, a determination cycle of the remaining time T is set relatively short in the initial stage when the V2L function is used, and the determination cycle of the remaining time T is set relatively long in a later stage when the V2L function is used. When the determination cycle of the remaining time T is set long, the number of pieces of data for determining the average power consumption amount P2 increases, and variability of the average power consumption amount P2 over time decreases.

For example, the remaining time T may be determined every 5 seconds when the V2L function is initially used, and the remaining time T may be determined every 30 seconds when the V2L function is later used. In addition, a period up to one hour from a time point when the external load 40 is connected to the battery 10 may be set to the initial stage of V2L usage.

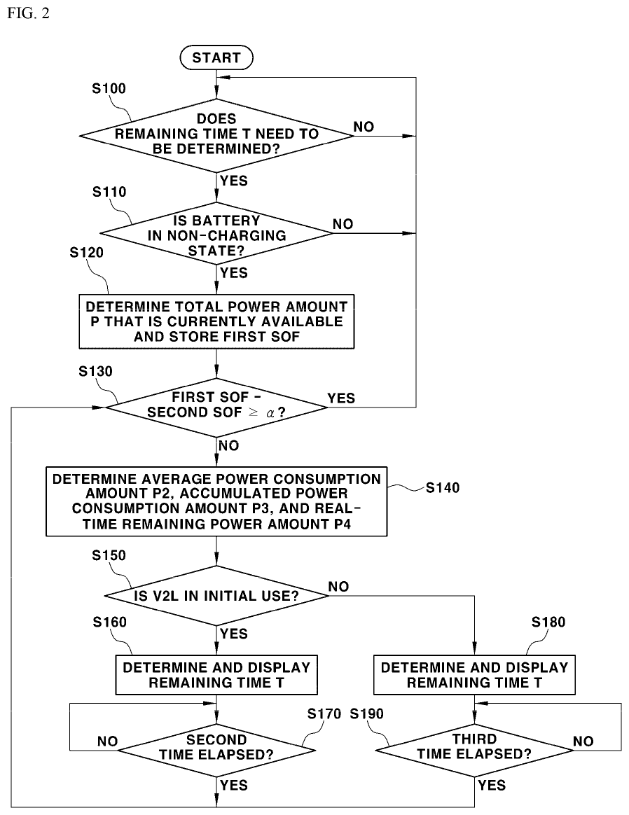

Hereinafter, a method of determining the power availability time of the fuel cell vehicle according to an embodiment of the present disclosure will be described with reference to FIG. 2.

As shown in FIG. 2, the processor 30 first determines whether it is necessary to determine the remaining time T during which the V2L function may be used (S100). The remaining time T is a remaining time during which the battery 10 and the fuel cell stack 20 may be supplied with power from the external load 40 and the internal load 50 from the present.

When it is determined that determination of the remaining time T is necessary, the processor 30 determines whether the battery 10 is being charged (S110). For example, the processor 30 may determine whether the battery 10 is being charged by detecting whether hardware for converting power output from the fuel cell stack 20 so that the battery 10 may be charged with the power is operating.

When the battery 10 is being charged, the processor 30 continuously monitors whether the battery 10 is being charged and waits. When the battery 10 is not being charged, the processor 30 determines the total power amount P that is currently available and stores information on the real-time SoF used in determining the total power amount P in a memory (S120). The total power amount P may be determined based on the real-time SoF of the fuel cell stack 20 and the real-time SoC of the battery 10. The memory may be provided in the processor 30.

According to an embodiment of the present disclosure, the SoF value stored in the memory is used as a reference value for determining whether to redetermine the total power amount P. Accordingly, the SoF value stored in the memory is named “first SoF” to distinguish the SoF value from the real-time SoF.

The processor 30 compares a value obtained by subtracting the current SoF from the first SoF stored in the memory with a predetermined value α (S130). In this way, the fluctuation and decrease of the SoF may be determined. For example, the value α may be set to 5% and may be tuned through a preliminary test, evaluation, etc.

When the value obtained by subtracting the current SoF from the first SoF is greater than or equal to the predetermined value α, the processor 30 redetermines the total power amount P (S120). In order to redetermine the total power amount P, the processor 30 may re-execute step S100 prior to step S120.

When the value obtained by subtracting the current SoF from the first SoF is less than the predetermined value α, the processor 30 determines the real-time remaining power amount P4 (S140). In order to determine the real-time remaining power amount P4, the processor 30 determines the real-time power consumption amount P1, the average power consumption amount P2, and the accumulated power consumption amount P3.

Before determining the remaining time T based on the real-time remaining power amount P4, the processor 30 may determine whether the V2L function is initially used (S150). The processor 30 may determine the V2L usage time based on a time point when the external load 40 is connected to the battery 10. The processor 30 may determine whether the V2L function is initially used by comparing the V2L usage time with a predetermined first time T1. When the V2L usage time is less than the first time T1, it may be determined that the V2L function is initially used, and when the V2L usage time is greater than or equal to the first time T1, it may be determined that the V2L function is not initially used.

When the V2L usage time is less than the first time T1, the processor 30 determines the remaining time T every time a predetermined second time T2 elapses and displays the remaining time T on a display of the vehicle (S160). For example, the display may be a cluster installed inside the vehicle.

In order to determine the remaining time T every time the second time T2 elapses, the processor 30 determines whether the second time T2 has elapsed from a time point when it is determined that determination of the remaining time T is necessary (S170). When it is determined that the second time T2 has elapsed, the processor 30 returns to step S130 and determines whether to redetermine the total power amount P. In addition, in order to determine the remaining time T every time the second time T2 elapses, when step S170 is re-executed, it is determined whether the second time T2 has elapsed from a time point when the remaining time T was last determined.

Meanwhile, when the V2L usage time is greater than or equal to the first time T1, the processor 30 determines the remaining time T every time a third time T3 set in advance elapses and displays the remaining time T on the display of the vehicle (S180).

In order to determine the remaining time T whenever the third time T3 elapses, the processor 30 determines whether the third time T1 has elapsed from the time point when the remaining time T was last determined (S190). When it is determined that the third time T3 has elapsed, the processor 30 returns to step S130 and determines whether to redetermine the total power amount P.

For example, the first time T1 may be 1 hour, the second time T2 may be 5 seconds, and the third time T3 may be 30 seconds. The first time T1, the second time T2, and the third time T3 may be tuned through a preliminary test and evaluation. A reason for tuning the time interval as described above is that, in a short time interval of less than 1 hour, a remaining time that reflects real-time usage needs to be determined, and thus updates are performed at relatively short time intervals. However, since fluctuation in the remaining time occurs when updates are performed at such short time intervals, the remaining time may be updated at longer time intervals after 1 hour.

According to the solution to the above-mentioned problem, the present disclosure may accurately determine a V2L available time (i.e., the remaining time) even in a mode in which the fuel cell stack is driven, such as the utility mode and the drive-ready mode, and thus provide the user with accurate information about the V2L available time.

The effects of the present disclosure are not limited to the effects described above, and other effects of the present disclosure not mentioned herein will be clearly understood by those skilled in the art to which the present disclosure pertains from the above description.

The embodiments of the present disclosure have been described in detail above, and the terms used in this specification and claims should not be interpreted as being limited to conventional or dictionary meanings. In addition, the scope of the rights of the present disclosure is not limited to the embodiments described above, and encompasses various modifications and improvements made by those skilled in the art using the basic concept of the present disclosure defined in the claims below.

What is claimed is:

1. An apparatus for determining a power availability time of a fuel cell vehicle, the apparatus comprising:
a battery installed in the vehicle;
a fuel cell stack configured to generate power allowed to be supplied to the battery; and
a processor configured to determine a currently available total power amount based on a state of charge (SoC) of the battery and a state of fuel (SoF) of the fuel cell stack based on power stored in the battery and power generated by the fuel cell stack being supplied to a load of the vehicle, and to determine a remaining time during which power is allowed to be supplied to an internal load and an external load of the vehicle based on a power consumption amount of the internal load and the external load and the total power amount.

2. The apparatus of claim 1, wherein the processor determines the remaining time based on the battery not being charged.

3. The apparatus of claim 1, wherein the processor determines a real-time SoF determined based on the external load being connected to the battery as a first SoF, determines an accumulated amount of power consumption used by the external load and the internal load based on a difference between the first SoF and a current SoF being less than a predetermined value, and determines a real-time remaining power amount by subtracting the accumulated power consumption amount from the total power amount.

4. The apparatus of claim 1, wherein the processor determines a real-time SoF determined based on the external load being connected to the battery as a first SoF, and redetermines the total power amount based on the SoC of the battery and the SoF of the fuel cell stack based on a difference between the first SoF and a current SoF being greater than or equal to a predetermined value.

5. The apparatus of claim 4, wherein the processor redetermines the first SoF based on the total power amount being redetermined, and the first SoF is determined to be a real-time SoF redetermined based on the total power amount being redetermined.

6. The apparatus of claim 1, wherein, based on a time for which the external load has been connected to the battery being less than a predetermined first time, the processor determines the remaining time at intervals of a predetermined second time.

7. The apparatus of claim 6, wherein, based on the time for which the external load has been connected to the battery being greater than or equal to the first time, the processor determines the remaining time at intervals of a predetermined third time.

8. The apparatus of claim 1, wherein the processor displays the remaining time through a display of the vehicle.

9. The apparatus of claim 3, wherein the processor determines the remaining time based on the accumulated power consumption amount, an average power consumption amount which is an average value of the accumulated power consumption amount, and the total power amount.

10. The apparatus of claim 1, wherein the processor receives information on the SoC of the battery from a BMS (Battery Management System) of the vehicle, and receives information on the SoF of the fuel cell stack from a FCU (Fuel cell Control Unit) of the vehicle.

11. A method of determining a power availability time of a fuel cell vehicle, the method comprising:
determining, by a processor, whether power of a battery installed in the vehicle and power of a fuel cell stack are supplied to a load of the vehicle;
determining, by the processor, an SoC of the battery based on power of the battery and the fuel cell stack being supplied to a load;
determining, by the processor, an SoF of the fuel cell stack based on the power of the battery and the fuel cell stack being supplied to the load;
determining, by the processor, a currently available total power amount based on the SoC of the battery and the SoF of the fuel cell stack; and
determining, by the processor, a remaining time during which power is allowed to be supplied to an internal load and an external load of the vehicle based on a power consumption amount of the internal load and the external load and the total power amount.

12. The method of claim 11, further comprising determining, by the processor, whether the battery is being charged, and wherein the remaining time is determined based on the battery not being charged.

13. The method of claim 11, comprising:
determining, by the processor, a real-time SoF determined based on the external load being connected to the battery to be a first SoF; and
determining, by the processor, an accumulated amount of power consumption used by the external load and the internal load, and an average power consumption amount which is an average value of the accumulated power consumption amount based on a difference between the first SoF and a current SoF being less than a predetermined value.

14. The method of claim 13, comprising redetermining, by the processor, the total power amount based on a difference between the first SoF and a current SoF being greater than or equal to the predetermined value.

15. The method of claim 13, comprising redetermining, by the processor, the first SoF based on the total power amount being redetermined,
wherein the first SoF is determined to be a real-time SoF redetermined based on the total power amount being redetermined.

16. The method of claim 11, comprising determining, by the processor, the remaining time at intervals of a predetermined second time based on a time for which the external load has been connected to the battery being less than a predetermined first time.

17. The method of claim 16, comprising determining, by the processor, the remaining time at intervals of a predetermined third time based on the time for which the external load has been connected to the battery being greater than or equal to the predetermined first time, wherein the third time is determined to be a time value greater than the second time.

18. The method of claim 11, comprising displaying, by the processor, the remaining time on a display of the vehicle.

19. The method of claim 13, comprising determining, by the processor, a real-time remaining power amount by subtracting the accumulated power consumption amount from the total power amount, and determining the remaining time by dividing the real-time remaining power amount by the average power consumption amount.

20. The method of claim 11, comprising receiving, by the processor, information on the SoC of the battery from a BMS of the vehicle, and receiving information on the SoF of the fuel cell stack from a FCU of the vehicle.
